(19) United States
(12) Patent Application Publication
(10) Pub. No.: US 2026/0341225 A1
(43) Pub. Date: Oct. 29, 2026

(54) DISPLAY MODULE AND DISPLAY APPARATUS

(71) Applicant: Tianma Advanced Display Technology Institute (Xiamen) Co., Ltd., Xiamen (CN)

(72) Inventors: Zhenyu JIA, Xiamen (CN); Chengfeng ZHANG, Xiamen (CN); Xuejing XIAO, Xiamen (CN); Shouzheng WU, Xiamen (CN); Yuanjian CUI, Xiamen (CN); Yongxin HE, Xiamen (CN); Yingteng ZHAI, Xiamen (CN); Liwei ZHANG, Xiamen (CN); Kerui XI, Xiamen (CN)

(73) Assignee: Tianma Advanced Display Technology Institute (Xiamen) Co., Ltd., Xiamen (CN)

(21) Appl. No.: 19/304,575

(22) Filed: Aug. 19, 2025

(30) Foreign Application Priority Data
Apr. 29, 2025 (CN) 202510554645.8

(51) Int. Cl. G09G 3/3266; H10H 29/49

(52) U.S. Cl. CPC G09G 3/3266; H10H 29/49; G09G 2300/0439; G09G 2320/0233; G09G 2330/021

(57) ABSTRACT

A display module and a display apparatus are disclosed in the present application. The display module comprises: a display substrate, comprising a plurality of first bonding pads arranged in a first direction, the display substrate comprising a first edge and a second edge opposite to each other in the first direction; a first circuit board, comprising a plurality of first connecting lines, a plurality of second bonding pads arranged in the first direction, and a plurality of third bonding pads arranged in the first direction, each of the second bonding pads being electrically connected to a corresponding one of the first bonding pads, an end of each of the first connecting lines being connected to a corresponding one of the second bonding pads, and the other end of each of the first connecting line being connected to a corresponding one of the third bonding pad; and a driver chip.

### CROSS-REFERENCE TO RELATED APPLICATIONS

This application claims priority to Chinese Patent Application No. 202510554645.8, titled “DISPLAY MODULE AND DISPLAY APPARATUS” and filed on Apr. 29, 2025, which is hereby incorporated by reference in its entirety.

### TECHNICAL FIELD

The present application relates to the field of display technology, and in particular to a display module and a display apparatus.

### BACKGROUND

The display module usually includes a display substrate and a driver chip, and the driver chip provides signals to the display substrate.

With the continuous development of science and technology, large-size display modules have emerged. Large-size display substrates require a large number of signals, which are often not met by one driver chip, and two or even more driver chips are required.

The arrangement orders of the signal bonding pads on both sides of the display substrate are often different, requiring chips with multiple pin arrangement orders, and thus requiring the moldings of multiple driver chips, resulting in an increase in the production cost of the display module.

### SUMMARY

The embodiments of the present application provide a display module and a display apparatus, which is conducive to reducing the production cost of the display module.

In the first aspect, the embodiments of the present application provide a display module, including: a display substrate, including a plurality of first bonding pads arranged in a first direction, the display substrate including a first edge and a second edge opposite to each other in the first direction; a first circuit board, including a plurality of first connecting lines, a plurality of second bonding pads arranged in the first direction, and a plurality of third bonding pads arranged in the first direction, each of the second bonding pads are electrically connected to a corresponding one of the first bonding pads, an end of each of the first connecting lines is connected to a corresponding one of the second bonding pads, and the other end of each of the first connecting lines is connected to a corresponding one of the third bonding pads; a driver chip, including a plurality of pins arranged in the first direction, the pins are electrically connected to the third bonding pads; wherein in the direction from the first edge to the second edge, the signals transmitted by an i^{th} one of the second bonding pads and an i^{th} one of the third bonding pads are different, where i≥1, and i is an integer.

In the second aspect, the embodiments of the present application provide a display apparatus, including the display module as described in the embodiment of the first aspect.

### BRIEF DESCRIPTION OF THE DRAWINGS

By reading the following detailed description of the non-limiting embodiments with reference to the drawings, other features, purposes and advantages of the present application will become more obvious, wherein the same or similar reference numerals represent the same or similar features, and the drawings are not drawn according to the actual scale.

FIG. 1 shows a side structural schematic diagram of a display module provided in an embodiment of the present application;

FIG. 2 shows a bonding pad arrangement schematic diagram of a display substrate provided in an embodiment of the present application;

FIG. 3 shows a connection schematic diagram of the display module provided in an embodiment of the present application;

FIG. 4 shows a schematic structural diagram of a first circuit board provided in an embodiment of the present application;

FIG. 5 shows another schematic structural diagram of the first circuit board provided in an embodiment of the present application;

FIG. 6 shows a backlight surface structural schematic diagram of the display module provided in an embodiment of the present application;

FIG. 7 shows another connection schematic diagram of the display module provided in an embodiment of the present application;

FIG. 8 shows a signal schematic diagram corresponding to FIG. 7;

FIG. 9 shows another backlight surface structural schematic diagram of the display module provided in an embodiment of the present application;

FIG. 10 shows another connection schematic diagram of the display module provided in an embodiment of the present application;

FIG. 11 shows a signal schematic diagram corresponding to FIG. 10;

FIG. 12 shows another side structural schematic diagram of the display module provided in an embodiment of the present application;

FIG. 13 shows a schematic diagram of another backlight surface structure of the display module provided in an embodiment of the present application;

FIG. 14 shows a schematic diagram of another backlight surface structure of the display module provided in an embodiment of the present application;

FIG. 15 shows a schematic diagram of a top view structure of the display substrate provided in an embodiment of the present application;

FIG. 16 shows a schematic diagram of another top view structure of the display substrate provided in an embodiment of the present application;

FIG. 17 shows a schematic diagram of another top view structure of the display substrate provided in an embodiment of the present application;

FIG. 18 shows a schematic diagram of another top view structure of the display substrate provided in an embodiment of the present application;

FIG. 19 shows a schematic diagram of another top view structure of the display substrate provided in an embodiment of the present application;

FIG. 20 shows a schematic structural diagram of the driver chip provided in an embodiment of the present application;

FIG. 21 shows a schematic diagram of a three-dimensional structure of the display substrate provided in an embodiment of the present application;

FIG. 22 shows a schematic diagram of a film layer structure of the display substrate provided in an embodiment of the present application;

FIG. 23 shows a schematic structural diagram of a display apparatus provided in an embodiment of the present application; and

FIG. 24 shows another schematic structural diagram of the display apparatus provided in an embodiment of the present application.

### DETAILED DESCRIPTION

The features and exemplary embodiments of various aspects of the present application will be described in detail below. In order to make the purpose, technical solutions and advantages of the present application clearer, the present application will be further described in detail below in conjunction with the drawings and specific embodiments. It should be understood that the specific embodiments described herein are only configured to explain the present application and are not configured to limit the present application. For those skilled in the art, the present application can be implemented without some of these specific details. The following description of the embodiments is only to provide a better understanding of the present application by showing examples of the present application.

It should be noted that in the present application, relational terms such as first and second are only used to distinguish one entity or operation from another entity or operation, and do not necessarily require or imply any such actual relationship or order between these entities or operations. Moreover, the terms “include”, “comprise” or any other variant thereof are intended to cover non-exclusive inclusion, so that a process, method, article or device including a series of elements includes not only those elements, but also other elements not explicitly listed, or also includes elements inherent to such a process, method, article or device. In the absence of further restrictions, the elements defined by the sentence “include . . . ” do not exclude the existence of other identical elements in the process, method, article or device including the elements.

It should be understood that when describing the structure of a component, when a layer or an area is referred to as being “above” or “above” another layer or another area, it may refer to being directly above another layer or another area, or including other layers or areas between it and another layer or another area. Moreover, if the component is turned over, the layer or area will be “below” or “under” another layer or another area.

It should be understood that the term “and/or” used in the present application is only a description of the association relationship of the associated objects, indicating that there may be three relationships, for example, A and/or B may represent: A exists alone, A and B exist at the same time, and B exists alone. In addition, the character “/” in the present application generally indicates that the associated objects before and after are in an “or” relationship.

In the embodiments of the present application, the term “electrically connected” may refer to the direct electrical connection of two components, or may refer to the electrical connection between two components via one or more other components.

The term “connection” may refer to “electrical connection” or “electrical connection without an intermediate transistor”. The term “insulation” may refer to “electrical insulation” or “electrical isolation”. The term “drive” may refer to “control” or “operation”. The display module can be a display apparatus or a module/part of a display apparatus.

It is obvious to those skilled in the art that various modifications and changes can be performed in the present application without departing from the gist or scope of the present application. Therefore, the present application is intended to cover modifications and changes of the present application that fall within the scope of the corresponding claims (technical solutions claimed for protection) and their equivalents. It should be noted that the implementation methods provided in the embodiments of the present application can be combined with each other without contradiction.

The embodiments of the present application provide a display module and a display apparatus, and the embodiments of the display module and the display apparatus will be described below in conjunction with the drawings.

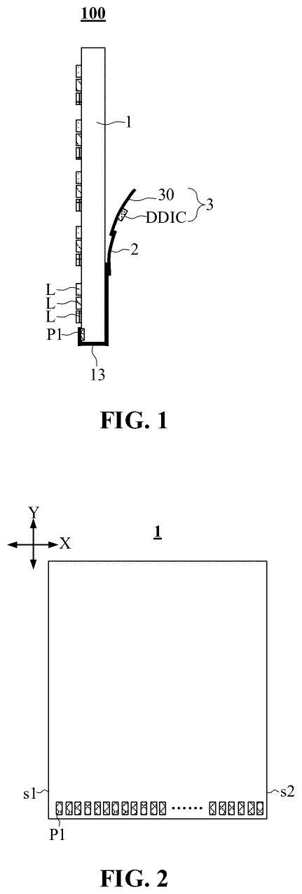

Referring to FIGS. 1, 2 and 3, the display module 100 provided in the embodiments of the present application includes a display substrate 1, a first circuit board 2, and a driver chip 3.

The display substrate 1 includes a plurality of first bonding pads P1 arranged in a first direction X. The display substrate 1 includes a first edge s1 and a second edge s2 opposite to each other in the first direction X. The first edge s1 and the second edge s2 extend in the second direction Y, and the first direction X and the second direction Y intersect with each other. For example, the first direction X is a row direction, and the second direction Y is a column direction.

Exemplarily, the display substrate 1 includes a pixel circuit (not shown in the figures). At least part of the first bonding pads P1 are electrically connected to the pixel circuit and the driver chip 3 and are configured to transmit the signal from the driver chip 3 to the pixel circuit. The display substrate 1 further includes a light-emitting element L electrically connected to the pixel circuit, and the pixel circuit is configured to drive the light-emitting element L to emit light. The light-emitting element L includes but is not limited to an inorganic light-emitting element (such as Micro LED or Mini LED) or an organic light-emitting element (such as OLED). The first bonding pad electrically connected to the pixel circuit is configured to transmit a data signal or a power supply signal.

Exemplarily, when the display substrate 1 includes a scan driving circuit (not shown in the figures), at least part of the first bonding pads P1 are electrically connected to the scan driving circuit and the driver chip 3 and are configured to transmit the signal from the driver chip 3 to the scan driving circuit. The scan driving circuit is also electrically connected to the pixel circuit, and the scan driving circuit is configured to drive the pixel circuit. The first bonding pads electrically connected to the scan driving circuit are configured to transmit a scan driving signal to drive the scan driving circuit to work.

Exemplarily, the light-emitting element L is located on the light-emitting side of the display substrate 1, and the first circuit board 2 and the driver chip 3 are located on the backlight side of the display substrate 1. It should be noted that in order to clearly show the first circuit board 2 and the driver chip 3 in FIG. 1, the first circuit board 2 and the driver chip 3 are not attached to the backlight surface of the display substrate 1 for illustration, which is not used to limit the present application. For example, the first circuit board 2 and the driver chip 3 can be attached to the backlight surface of the display substrate 1.

The first circuit board 2 includes a plurality of first connecting lines 21, a plurality of second bonding pads P2 arranged in the first direction X, and a plurality of third bonding pads P3 arranged in the first direction X. Each of the second bonding pads P2 is electrically connected to the corresponding one of the first bonding pads P1. An end of the first connecting line 21 is connected to the second bonding pad P2, and the other end of the first connecting line 21 is connected to the third bonding pad P3.

Exemplarily, the first circuit board 2 includes a flexible printed circuit board (FPC). In other examples, the first circuit board 2 can further be a non-flexible printed circuit board.

The driver chip 3 includes a plurality of pins 31 arranged in the first direction X, and the pins 31 are electrically connected to the third bonding pads P3.

The signals output by the pins 31 of the driver chip 3 are transmitted to the first bonding pads P1 through the third bonding pads P3, the first connecting lines 21, and the second bonding pads P2 in sequence, then the signals provided by the driver chip 3 are transmitted to the pixel circuit by the first bonding pads P1, and the pixel circuit drives the light-emitting element L to emit light based on the signals provided by the driver chip 3.

In the direction from the first edge s1 to the second edge s2, the 1st second bonding pad P2, the 2nd second bonding pad P2, the 3rd second bonding pad P2 . . . are arranged in sequence. In the direction from the first edge s1 to the second edge s2, the 1st third bonding pad P3, the 2nd third bonding pad P3, the 3rd third bonding pad P3 . . . are arranged in sequence. It can be understood that among the plurality of second bonding pads P2, the 1st second bonding pad P2 is closest to the first edge s1, and the last second bonding pad P2 is closest to the second edge s2. Among the plurality of third bonding pads P3, the 1st third bonding pad P3 is closest to the first edge s1, and the last third bonding pad P3 is closest to the second edge s2.

In the direction from the first edge s1 to the second edge s2, the signals transmitted by the i^{th} second bonding pad P2 and the i^{th} third bonding pad P3 are different, i≥1, and i is an integer. There are a number i−1 of second bonding pads P2 between the i^{th} second bonding pad P2 and the first edge s1, and there are i−1 third bonding pads P3 between the i^{th} third bonding pad P3 and the first edge s1. The direction from the first edge s1 to the second edge s2 is parallel to the first direction X. In the drawings of the present application, the direction from the first edge s1 to the second edge s2 is taken as an example from left to right.

It can be understood that among the multiple second bonding pads P2 and the multiple third bonding pads P3, the second bonding pads P2 and the third bonding pads P3 electrically connected to each other are the same group of bonding pads, and there is at least one group of second bonding pads P2 and third bonding pads P3 with the same arrangement order but different transmitted signals.

For example, i=1, the 1st second bonding pad P2 transmits the ground voltage signal COM, and the 1st third bonding pad P3 transmits the second power supply signal PVEE.

For another example, i=2, the 2nd second bonding pad P2 transmits the scan trigger signal STV, and the 2nd third bonding pad P3 transmits the second power supply signal PVEE.

For another example, i=8, the eighth second bonding pad P2 transmits the data signal data, and the 8th third bonding pad P3 transmits the first power supply signal PVDD; and so on.

The voltage of the first power supply signal PVDD is greater than the voltage of the second power supply signal PVEE. For example, the first power supply signal PVDD is a positive voltage, and the second power supply signal PVEE is a negative voltage.

The second bonding pad P2 and the third bonding pad P3 are electrically connected through the first connecting line 21. The first circuit board 2 includes a plurality of first connecting lines 21, and at least two first connecting lines 21 have a cross portion, so that there is at least one group of second bonding pads P2 and third bonding pads P3 with the same arrangement order but different transmitted signals. Here, “cross” means that at least two first connecting lines 21 overlap in the thickness direction of the first circuit board 2.

According to the display module provided by the embodiments of the present application, the second bonding pad of the first circuit board is electrically connected to the first bonding pad of the display substrate, the third bonding pad of the first circuit board is electrically connected to the pin of the driver chip, the second bonding pad and the third bonding pad are electrically connected through the first connecting line, and in the direction from the first edge to the second edge, the signals transmitted by the i^{th} second bonding pad and the i^{th} third bonding pad are different. The third bonding pad of the first circuit board is connected to the signal provided by the pin of the driver chip, and the second bonding pad of the first circuit board outputs the signal to the first bonding pad of the display substrate. Since there is at least one group of the second bonding pads and the third bonding pads in the first circuit board with the same arrangement order but different transmitted signals, the driver chip can rearrange the output signals through the first circuit board, so that when multiple driver chips are needed, it is convenient to use multiple driver chips with the same arrangement order of output signals, which is conducive to reducing the production cost of the display module.

In some embodiments, in the direction from the first edge s1 to the second edge s2, the signals transmitted by the i^{th} first bonding pad P1 and the i^{th} second bonding pad P2 are the same, and the signals transmitted by the i^{th} third bonding pad P3 and the i^{th} pin 31 are the same.

The i^{th} first bonding pad P1 and the i^{th} second bonding pad P2 are electrically connected, and the i^{th} third bonding pad P3 is electrically connected to the i^{th} pin 31.

Exemplarily, multiple first bonding pads P1 and multiple second bonding pads P2 are electrically connected in one-to-one correspondence. Specifically, the 1st first bonding pad P1 and the 1st second bonding pad P2 are electrically connected, the 2nd first bonding pad P1 and the 2nd second bonding pad P2 are electrically connected, the 3rd first bonding pad P1 and the 2nd second bonding pad P2 are electrically connected, and so on.

Multiple third bonding pads P3 are electrically connected to multiple pins 31 in one-to-one correspondence. Specifically, the 1st third bonding pad P3 is electrically connected to the 1st pin 31, the 2nd third bonding pad P3 is electrically connected to the third pin 31, the 3rd third bonding pad P3 is electrically connected to the third pin 31, and so on.

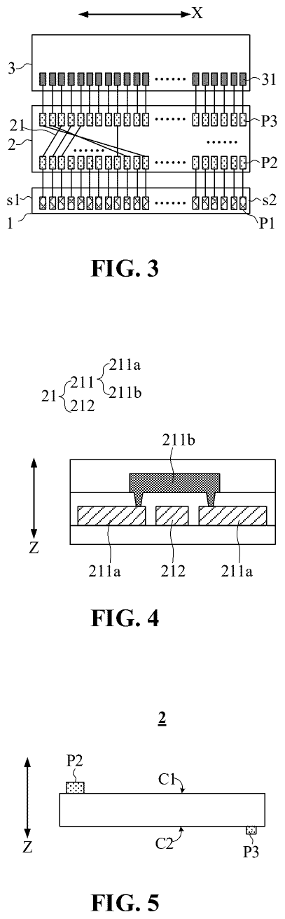

Exemplarily, as shown in FIG. 3, multiple first bonding pads P1 and multiple second bonding pads P2 can be connected in one-to-one correspondence, and multiple third bonding pads P3 and multiple pins 31 can be connected in one-to-one correspondence. For example, the third bonding pad P3 and the pin 31 can be press-fitted and connected. Specifically, the third bonding pad P3 and the pin 31 can be press-fitted and connected through anisotropic conductive adhesive (ACF). It should be noted that in order to clearly illustrate the one-to-one correspondence between multiple third bonding pads P3 and multiple pins 31 in FIG. 3, the third bonding pad P3 and the pin 31 are connected with a trace for illustration, which is not used to limit the present application.

In this example, the i^{th} first bonding pad P1 and the i^{th} second bonding pad P2 transmit the same signal, and the i^{th} third bonding pad P3 and the i^{th} pin 31 transmit the same signal, which facilitates the press-fitted connection between the third bonding pad P3 and the pin 31.

In some embodiments, in the direction from the first edge s1 to the second edge s2, the plurality of second bonding pads P2 and the plurality of pins 31 are arranged in the same order and transmit different signals.

For example, taking FIG. 3 as an example, the bonding pads and the pins connected together by the traces represent the bonding pads and the pins that transmit the same signals, and the bonding pads and the pins that are not connected together represent the bonding pads and the pins that transmit different signals.

For example, the 1st second bonding pad P2 transmits the ground voltage signal COM, and the 1st third bonding pad P3 transmits the second power supply signal PVEE; the 2nd second bonding pad P2 transmits the scan trigger signal STV, and the 2nd third bonding pad P3 transmits the second power supply signal PVEE; and the 8th second bonding pad P2 transmits the data signal data, and the 8th third bonding pad P3 transmits the first power supply signal PVDD; and so on.

Still taking for an example that the second bonding pads P2 and the third bonding pads P3 electrically connected to each other are the same group of bonding pads among the multiple second bonding pads P2 and the multiple third bonding pads P3, in this embodiment, there are multiple groups of second bonding pads P2 and third bonding pads P3 with the same arrangement order but different transmitted signals, so that it is easier for the driver chip 3 to realize the rearrangement of the signals output to the display substrate through the first circuit board 2.

In some embodiments, in the direction from the first edge s1 to the second edge s2, the j^{th} second bonding pad P2 and the j^{th} pin 31 transmit the same signal, i≠j, j≥1, and j is an integer.

Exemplarily, the j^{th} second bonding pad P2 and the j^{th} pin 31 can be electrically connected, and the j^{th} second bonding pad P2 and the j^{th} first bonding pad P1 can be electrically connected.

Exemplarily, in the direction from the first edge s1 to the second edge s2, the plurality of second bonding pads P2 and the plurality of pins 31 are arranged in the same order and transmit different signals. In addition, the plurality of second bonding pads P2 and the plurality of pins 31 are arranged in the same order and transmit the same signals.

In this embodiment, when the first circuit board 2 transmits the signal from the j^{th} pin 31 of the driver chip 3 to the display substrate 1, it is not necessary to rearrange the signal of the j^{th} pin 31; that is, when the first circuit board 2 transmits the signal of the driver chip 3 to the display substrate 1, the signals of some pins 31 can be rearranged, and the signals of other pins 31 are not rearranged, thereby simplifying the complexity of signal rearrangement.

In some embodiments, the first circuit board 2 includes multiple metal layers disposed in an insulated manner, and the crossing portions of different first connecting lines 21 are arranged in different metal layers.

For the same first connecting line 21, if part of the line segments of the first connecting line 21 are located in the first metal layer and the other part of the line segments are located in the second metal layer, the line segments of the first connecting line 21 located in different metal layers can be connected through vias.

As an example, referring to FIG. 4, the first connecting line 21 includes a first sub-connecting line 211 and a second sub-connecting line 212 that cross each other. The first sub-connecting line 211 includes a first section 211a and a second section 211b that are electrically connected to each other. The second section 211b and the second sub-connecting line 212 overlap in the thickness direction Z of the first circuit board. The first section 211a and the second sub-connecting line 212 may be located in one of the metal layers of the first circuit board, and the second section 211b may be located in another metal layer of the first circuit board. Different metal layers of the first circuit board are provided with the insulating layers therebetween.

In this embodiment, when the first circuit board 2 realizes signal rearrangement, the mutual crosstalk between signals of different first connecting lines 21 can be prevented to ensure the accuracy of signal transmission.

In some embodiments, as shown in FIG. 1, the driver chip 3 includes a display driver chip DDIC and a film 30. The display driver chip DDIC is electrically connected to the film 30, and the film 30 includes multiple metal layers.

Exemplarily, the driver chip 3 may adopt Chip On Flex (COF) technology, which refers to a chip soft film assembly technology that fixes an integrated circuit (IC) on a flexible printed circuit board. The display driver chip DDIC is fixed on the film 30, and the film 30 includes a plurality of pins 31. The display driver chip DDIC is configured to provide a data signal, and the data signal provided by the display driver chip DDIC is transmitted to the pins 31 through the traces in the film 30.

Exemplarily, the film 30 includes a plurality of metal layers, which facilitates the trace of the film 30 to cross the line when necessary.

In some embodiments, as shown in FIG. 5, the second bonding pad P2 is located on the first side C1 of the first circuit board 2, and the third bonding pad P3 is located on the second side C2 of the first circuit board 2, and the first side C1 and the second side C2 are opposite in the thickness direction Z of the first circuit board 2.

In this example, the first circuit board 2 adopts a double-layer structure, which facilitates the first connecting line 21 in the first circuit board 2 to cross the line.

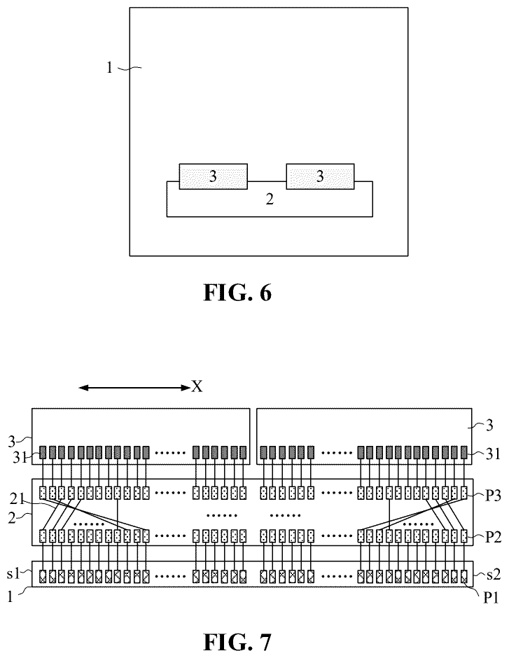

In some embodiments, as shown in FIG. 6, the first circuit board 2 is electrically connected to multiple driver chips 3. FIG. 6 shows that the number of driver chips 3 is two, which is not intended to limit the present application. For example, in other examples, the number of driver chips 3 may be 3, 4 or more.

Taking FIG. 7 as an example, for any driver chip 3, in the direction from the first edge s1 to the second edge s2, the 1st pin 31, the 2nd pin 31, the 3rd pin 31 . . . are arranged in sequence. It can be understood that for any driver chip 3, among the multiple pins 31, the 1st pin 31 is closest to the first edge s1, and the last pin 31 is closest to the second edge s2. In the direction from the first edge s1 to the second edge s2, the k^{th} pins 31 in different driver chips 3 transmit the same signal, k≥1, and k is an integer. The k^{th} pin 31 is any pin in the driver chip 3.

For example, k=1, and the 1st pins 31 of different driver chips 3 each transmit the second power supply signal PVEE.

For another example, k=2, the 2nd pins 31 of different driver chips 3 each transmit the second power supply signal PVEE.

For another example, k=8, the 8th pins 31 of different driver chips 3 each transmit the first power supply signal PVDD; and so on.

It is understandable that the third bonding pads P3 electrically connected to the k^{th} pins 31 in different driver chips 3 transmit the same signal.

Exemplarily, multiple pins 31 of multiple driver chips 3 are electrically connected to multiple third bonding pads P3 in one-to-one correspondence. The numbers of pins 31 of different driver chips 3 are the same.

In some embodiments, in the direction from the first edge s1 to the second edge s2, the multiple pins 31 in multiple driver chips 3 have the same arrangement orders and transmit the same signals.

For example, in each driver chip 3, the pin 31 closest to the first edge s1 is the 1st pin, and the pin 31 closest to the second edge s2 is the last pin. The 1st pins 31 in different driver chips 3 transmit the same signal, the 2nd pins 31 in different driver chips 3 transmit the same signal, and the 3rd pins 31 in different driver chips 3 transmit the same signal, and so on. The last pins 31 in different driver chips 3 transmit the same signal.

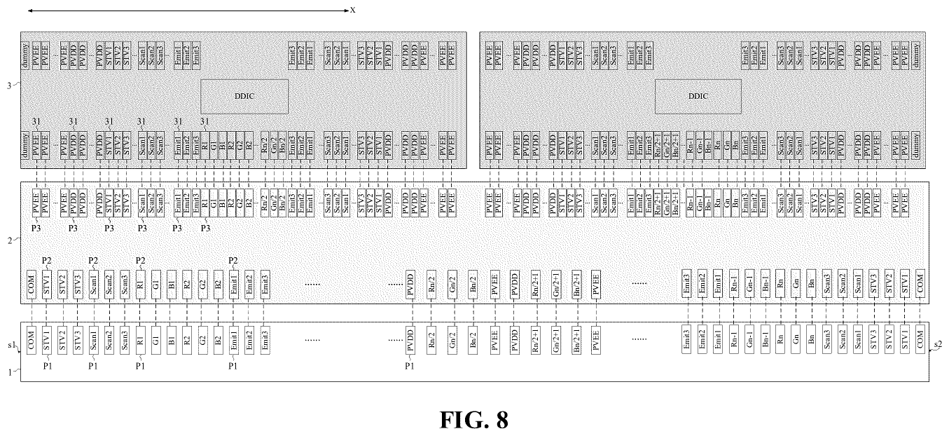

As an example, as shown in FIG. 8, the display module includes multiple driver chips 3 (for example, two driver chips), and the arrangement order of multiple pins 31 in different driver chips 3 is the same and the signals transmitted are the same. In the drawings of the present application, PVDD and PVEE represent different power supply signals, STV1-STV3, Scan1-Scan3, and Emit1-Emit3 represent different scan driving signals, R1-Rn represent data signals for driving red light-emitting elements, G1-Gn represent data signals for driving green light-emitting elements, and B1-Bn represent data signals for driving blue light-emitting elements.

It should be noted that the specific signals transmitted by the pins 31 of the driver chip 3 in various arrangement orders can be determined according to actual needs, and this application does not limit this.

In this embodiment, the arrangement orders of the multiple pins 31 in the multiple driver chips 3 are the same and the transmitted signals of them are the same. In this way, multiple driver chips 3 of the same structure can be directly used, and there is no need to prepare driver chips with multiple signal pin arrangement orders, thereby reducing the production cost of the display module.

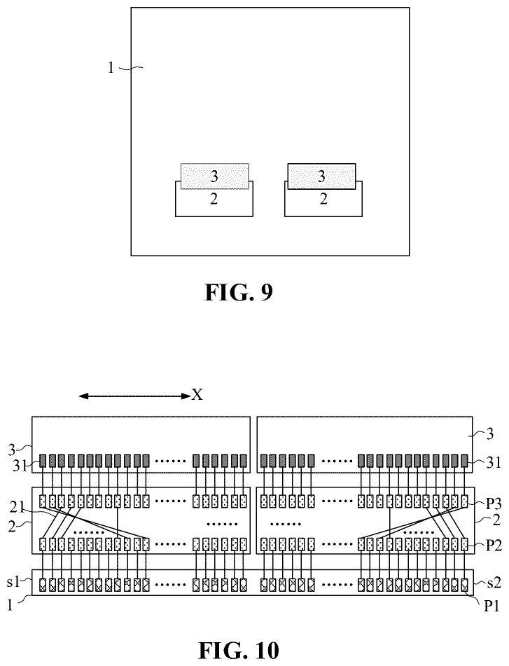

In some embodiments, referring to FIGS. 9 and 10, the display module includes multiple first circuit boards 2, and different first circuit boards 2 are electrically connected to different first bonding pads P1. In the direction from the first edge s1 to the second edge s2, the signals transmitted by the s^{th} second bonding pads P2 in different first circuit boards 2 are different, s≥1, and s is an integer.

In FIG. 9, the number of first circuit boards 2 is two for illustration, which is not used to limit the present application. For example, in other examples, the number of first circuit boards 2 may be 3, 4 or more.

Taking FIG. 10 as an example, for any first circuit board 2, in the direction from the first edge s1 to the second edge s2, the 1st second bonding pad P2, the 2nd second bonding pad P2, the 3rd second bonding pad P2 . . . are arranged in sequence. It can be understood that for any first circuit board 2, among the multiple second bonding pads P2, the 1st second bonding pad P2 is closest to the first edge s1, and the last second bonding pad P2 is closest to the second edge s2. The s^{th} second bonding pad P2 is any second bonding pad in the first circuit board 2.

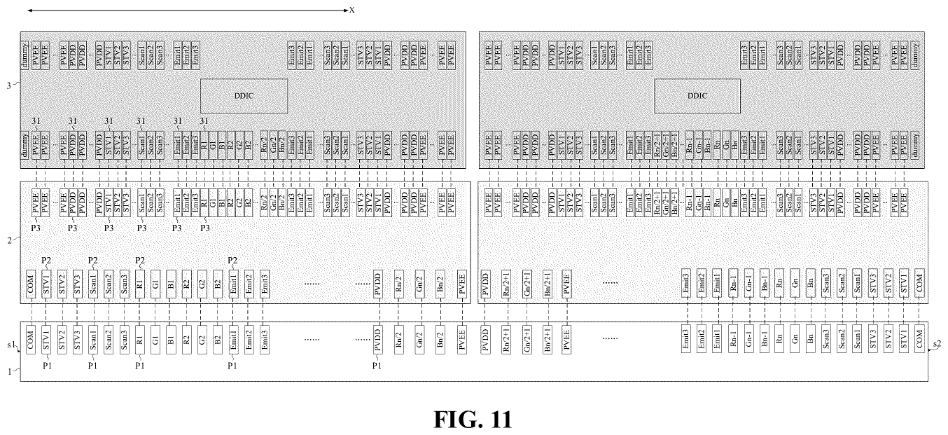

As an example, as shown in FIG. 11, the similarities between FIG. 11 and FIG. 8 are not repeated, and the differences include: FIG. 11 shows that the display module includes multiple first circuit boards 2 (for example, two first circuit boards 2) and multiple driver chips 3 (for example, two driver chips), and the signals transmitted by the s^{th} second bonding pads P2 in different first circuit boards 2 are different. In addition, in FIG. 11, the signals transmitted by the s^{th} third bonding pads P3 in different first circuit boards 2 are the same; the signals transmitted by the s^{th} pins 31 in different driver chips 3 are the same.

Exemplarily, in FIG. 11, in different first circuit boards 2, the arrangement orders of multiple second bonding pads P2 are the same, but the transmitted signals of them are different; in different first circuit boards 2, the arrangement orders of multiple third bonding pads P3 are the same, and the transmitted signals of them are the same; and the arrangement orders of multiple pins 31 in different driver chips 3 are the same, and the transmitted signals of them are the same.

For large-sized display modules, more signals are required, and the number of first bonding pads of the display substrate is relatively large. In this embodiment, the number of first circuit boards 2 is set to be plural, so that for a single first circuit board 2, its width in the first direction X can be reduced, and the difficulty of preparing a small-sized circuit board may be reduced compared with preparing a circuit board with a larger width. In addition, the signals transmitted by the s^{th} second bonding pads P2 in different circuit boards are different, so that it is convenient for the driver chip to transmit different signals to the display substrate through multiple first circuit boards. In addition, when the size of the display substrate is constant, the number of second bonding pads P2 on each first circuit board 2 can be less by providing multiple first circuit boards 2 compared with only one, so the wiring difficulty of the first circuit board 2 may also be lower.

Exemplarily, multiple second bonding pads P2 and multiple first bonding pads P1 in multiple first circuit boards 2 are electrically connected in one-to-one correspondence. The numbers of second bonding pads P2 in different first circuit boards 2 are the same. The numbers of third bonding pads P3 in different first circuit boards 2 are the same.

In some embodiments, the number of first circuit boards 2 is the same as the number of driver chips 3. For example, the number of first circuit boards 2 and the number of driver chips 3 are both two. Alternatively, the number of first circuit boards 2 and the number of driver chips 3 are both three; and so on. The specific number of first circuit boards 2 and driver chips 3 can be designed according to actual needs, and this application does not limit this.

In this embodiment, the number of first circuit boards 2 is the same as the number of driver chips 3, and the first circuit boards 2 and driver chips 3 can be electrically connected in one-to-one correspondence, which facilitates the connection between the first circuit board 2 and the driver chip 3.

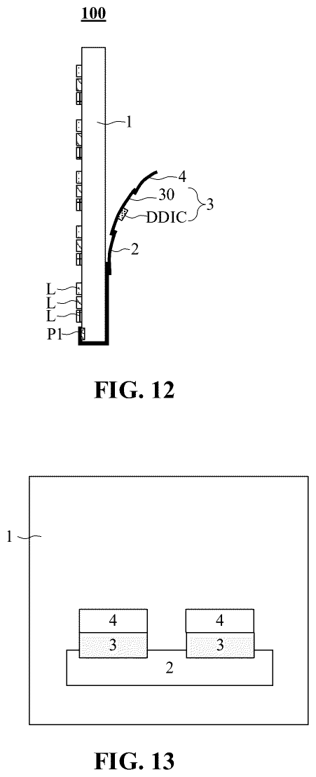

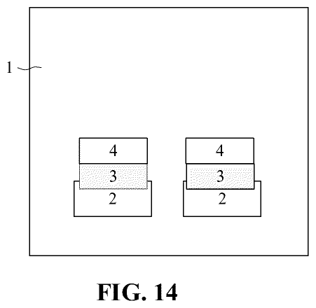

In some embodiments, as shown in FIGS. 12 to 14, the display module further includes a second circuit board 4, and the second circuit board 4 is electrically connected to the driver chip 3.

Exemplarily, the second circuit board 4 includes but is not limited to FPC.

Exemplarily, the driver chip 3 adopts COF technology, and the driver chip 3 includes a display driver chip DDIC and a film 30. The display driver chip DDIC and the second circuit board 4 are electrically connected to different pins of the film. The display driver chip DDIC is configured to provide data signals. The second circuit board 4 is configured to electrically connect the timing driver and/or the power supply chip (not shown in the figure). The timing driver is configured to provide a scan driving signal. For example, the display driver chip DDIC is configured to provide the data signals R1-Rn, G1-Gn, B1-Bn shown in FIG. 6 or FIG. 9; the timing driver is configured to provide the scan driving signals STV1-STV3, Scan1-Scan3, Emit1-Emit3 shown in FIG. 6 or FIG. 9; the power supply chip is configured to provide the power supply signals PVDD and PVEE shown in FIG. 6 or FIG. 9.

When the film 30 is a flexible film, it is soft and cannot be directly connected to the timing driver and/or the power supply chip. In this embodiment, a second circuit board 4 is further provided to connect the film 30 to the timing driver and/or the power supply chip, which can improve the reliability of the display module.

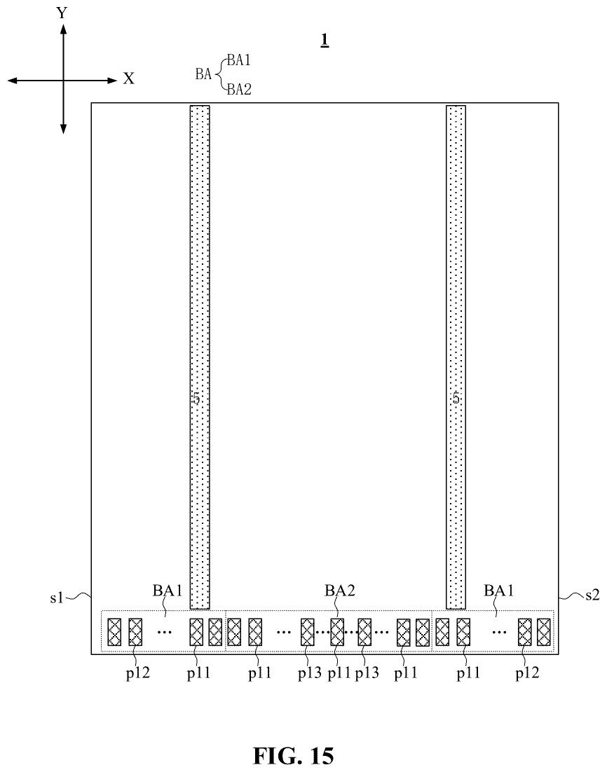

In some embodiments, as shown in FIG. 15, the first bonding pad includes a first data bonding pad p11, a first scan bonding pad p12, and a first power supply bonding pad p13. The first data bonding pad p11 transmits a data signal, the first scan bonding pad p12 transmits a scan driving signal, and the first power supply bonding pad p13 transmits a power supply signal.

The display substrate 1 includes a binding area BA, the binding area BA includes a first area BA1 and a second area BA2, the first area BA1 includes a first data bonding pad p11 and a first scan bonding pad p12, and the second area BA2 includes a first data bonding pad p11 and a first power supply bonding pad p13.

Exemplarily, a plurality of first data bonding pads p11 are respectively configured to transmit data signals R1-Rn, G1-Gn, B1-Bn, and a plurality of first scan bonding pads p12 are respectively configured to transmit STV1-STV3, Scan1-Scan3, Emit1-Emit3.

Exemplarily, the display substrate includes a plurality of pixel circuit columns. Each pixel circuit column includes a plurality of pixel circuits arranged in the second direction. In a large-size display panel, the number of pixel circuit columns is relatively large, and the number of required first data bonding pads is also relatively large. Compared with the plurality of first data bonding pads concentrated in one area, in this embodiment, the binding area of the display substrate includes a first area and a second area. The first data bonding pad p11 and the first scan bonding pad p12 are arranged in the first area BA1, and the first data bonding pad p11 and the first power supply bonding pad p13 are arranged in the second area BA2. In this way, the first data bonding pad p11 is included in two areas, and the connecting line between the first data bonding pad p11 and the pixel circuit column may not be too long from an overall point of view, which is conducive to the design of a narrow bezel. In addition, if multiple first data bonding pads P1 are centrally arranged and then connected to the pixel circuit column through connecting lines, the length difference of connecting lines may be very large, which causes the signal to be uneven, and finally leads to uneven brightness in the panel. In this embodiment, it is equivalent to setting multiple first data bonding pads P1 in a dispersed manner, which can improve the problem of uneven brightness.

As an example, a scan driving circuit is arranged on the display substrate 1, and the scan driving circuit is configured to drive the pixel circuit. The scan driving signal is a signal for driving the scan driving circuit. The scan driving signal includes but is not limited to a trigger signal STV, a clock signal CK, a high level signal VGH, a low level signal VGL.

As another example, the scan driving circuit is not arranged on the display substrate 1, and the scan driving signal is a signal for directly driving the pixel circuit.

In some embodiments, in the first direction X, the first area BA1 is arranged on each of both sides of the second area BA2. The second area BA2 can be understood as a central bonding pad area, and the first area BAL can be understood as an edge bonding pad area. The first area BA1 includes a first scan bonding pad p12, which facilitates bilateral driving of the pixel circuits in the same row in the first direction X to improve the display unevenness caused by signal delay or voltage drop.

The following is an exemplary introduction to some examples of the first scan bonding pad and the first data bonding pad.

In some embodiments, as shown in FIG. 15, the display substrate 1 includes a scan driving circuit 5 electrically connected to the first scan bonding pad p12. In the second direction Y, the scan driving circuit 5 at least partially overlaps with the first area BA1, and the scan driving circuit 5 does not overlap with the second area BA2, and the first direction X and the second direction Y intersect.

A first scan bonding pad p12 is provided in the first area BA1. In the second direction Y, if the scan driving circuit 5 at least partially overlaps with the first area BA1, the first scan bonding pad p12 can be connected to the scan driving circuit 5 nearby to shorten the length of the connecting trace between the first scan bonding pad and the scan driving circuit, thereby reducing the voltage drop of the connecting line.

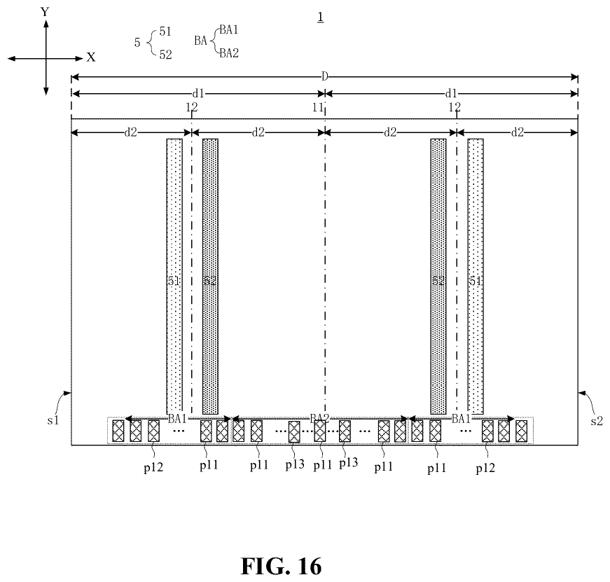

In some embodiments, as shown in FIG. 16, the display substrate 1 includes a first center line 11 and a second center line 12 that extend in the second direction Y. The width of the display substrate 1 in the first direction X is D, and the spacing between the first center line 11 and the first edge s1 in the first direction X is d1, and the spacing between the second center line 12 and the first center line 11 in the first direction X is d2, where d1=D/2, and d2=D/4. The scan driving circuit 5 is adjacent to the second center line 12. In the second direction Y, the first area BA1 overlaps with the second center line 12, and the second area BA2 overlaps with the first center line 11.

It should be noted that the first center line 11 and the second center line 12 are located in the display area, and the first center line 11, the second center line 12, and the first edge s1 are parallel or approximately parallel. The first center line 11 and the second center line 12 do not represent the real traces of the display substrate, and can be understood as the position center line virtually defined of the display substrate, that is, the first center line 11 and the second center line 12 are used to indicate the positions. The terms “equal”, “equal to”, and “=” as defined in the present application for two or more parameters are not absolutely equal but allow for a certain margin of error. It should be noted that the equal distances mentioned in the present application refer to the distance values being equal within the allowable error range of (±5%).

The display substrate 1 includes two second center lines 12, and a scan driving circuit 5 is arranged beside each of the two second center lines 12. In the second direction Y, the first area BA1 overlaps with the second center lines 12; the scan driving circuit 5 arranged beside the second center lines 12 can be connected to the first scan bonding pad p12 in the first area BA1 nearby.

In some embodiments, referring to FIG. 8 or FIG. 11, the first bonding pad P1 for transmitting data signals R1-Rn, G1-Gn, and B1-Bn is the first data bonding pad, the first bonding pad P1 for transmitting scan driving signals STV1-STV3, Scan1-Scan3, and Emit1-Emit3 is the first scan bonding pad, and the first bonding pad P1 for transmitting power supply signals PVDD and PVEE is the first power supply bonding pad.

The first area BA1 includes a plurality of first data bonding pads and a plurality of first scan bonding pads. In the first direction X, the plurality of first data bonding pads and the plurality of first scan bonding pads in the first area BA1 are arranged crosswise.

In the first direction X, the plurality of first data bonding pads and the plurality of first scan bonding pads in the first area BA1 are arranged crosswise, including but not limited to the following examples.

For example, in the first direction X, the first bonding pads in the first area BA1 are arranged in the order of first scan bonding pad, first data bonding pad, first scan bonding pad, and first data bonding pad, that is, in the first direction X, there is a first scan bonding pad between every two adjacent first data bonding pads in the first area BA1, and there is a first data bonding pad between every two adjacent first scan bonding pads.

For another example, in the first direction X, there are a plurality of first scan bonding pads between two adjacent first data bonding pads in the first area BA1, and/or there are a plurality of first data bonding pads between two adjacent first scan bonding pads.

It can be understood that there is at least one first scan bonding pad between two adjacent first data bonding pads in the first area BA1, and there is at least one first data bonding pad between two adjacent first scan bonding pads. This can be regarded as multiple first data bonding pads and multiple first scan bonding pads in the first area BA1 are arranged crosswise in the first direction X.

In a large-size display panel, the number of pixel circuit columns is large, and multiple pixel circuit columns are usually evenly arranged in the first direction. In this embodiment, multiple first data bonding pads and multiple first scan bonding pads in the first area BA1 are arranged crosswise. In this way, multiple first data bonding pads in multiple first areas can be roughly evenly distributed, and the first data bonding pads can be connected to the pixel circuit columns nearby to shorten the lengths of the connecting traces between the first data bonding pads and the pixel circuit columns, thereby reducing the voltage drop of the connecting traces.

In some embodiments, in the first direction, the first scan bonding pad on the first side of the first data bonding pad in the first area transmits the first scan driving signal, and the first scan bonding pad on the second side of the first data bonding pad in the first area transmits the second scan driving signal.

For example, referring to FIG. 8 or FIG. 11, the display substrate includes two first areas BA1, the 1st first area BA1 is located between the first edge s1 and the second area BA2, the first bonding pad P1 in the 1st first area BA1 that transmits the data signals R1, R2 . . . , G1, G2 . . . , B1, B2 . . . is the first data bonding pad, and the first bonding pad P1 in the 1st first area BA1 that transmits the scan driving signals STV1-STV3, Scan1-Scan3, and Emit1-Emit3 is the first scan bonding pad. For example, the scan driving signals STV1-STV3, and Scan1-Scan3 are the first scan driving signals, the scan driving signals Emit1-Emit3 are the second scan driving signals, the first scan bonding pad on the first side of the first data bonding pad that transmits the data signals R1, R2, G1, G2, B1, B2 transmits the first scan driving signals, and the first scan bonding pad on the first side of the first data bonding pad that transmits the data signals R1, R2, G1, G2, B1, B2 transmits the second scan driving signals.

The 2nd first area BA1 is located between the second edge s2 and the second area BA2. The first bonding pad P1 transmitting the data signals Rn, Rn-1 . . . , Gn, Gn-1 . . . , Bn, Bn-1 . . . in the second first area BA1 is the first data bonding pad, and the first bonding pad P1 transmitting the scan driving signals STV1-STV3, Scan1-Scan3, and Emit1-Emit3 in the second first area BA1 is the first scan bonding pad. For example, the scan driving signals STV1-STV3, and Scan1-Scan3 are the first scan driving signals, the scan driving signals Emit1-Emit3 are the second scan driving signals, the first scan bonding pad on the first side of the first data bonding pad transmitting the data signals Rn, Rn-1, Gn, Gn-1, Bn, Bn-1 transmits the first scan driving signals, and the first scan bonding pad on the first side of the first data bonding pad transmitting the data signals Rn, Rn-1, Gn, Gn-1, Bn, Bn-1 transmits the second scan driving signals.

In this embodiment, in the first direction, the first scan bonding pads on both sides of the first data bonding pad in the first area are configured to transmit different scan driving signals. In this way, the first scan bonding pads of different scan driving signals required by the scan driving circuit can be separated by the first data bonding pads to reduce mutual interference between different scan driving signals.

Exemplarily, the first scan driving signal and the second scan driving signal can be configured to drive different scan driving circuits.

In some embodiments, at least one first scan bonding pad p12 is electrically connected to different scan driving circuits 5. In other words, at least one first scan bonding pad p12 can provide signals to multiple scan driving circuits 5. For example, the first scan bonding pad p12 that transmits the high level signal VGH is electrically connected to different scan driving circuits 5. For another example, the first scan bonding pad p12 that transmits the low level signal VGL is electrically connected to different scan driving circuits 5.

In this embodiment, at least one first scan bonding pad p12 is electrically connected to different scan driving circuits 5, and multiple scan driving circuits 5 can share at least one first scan bonding pad, which can reduce the number of first scan bonding pads and simplify the structure.

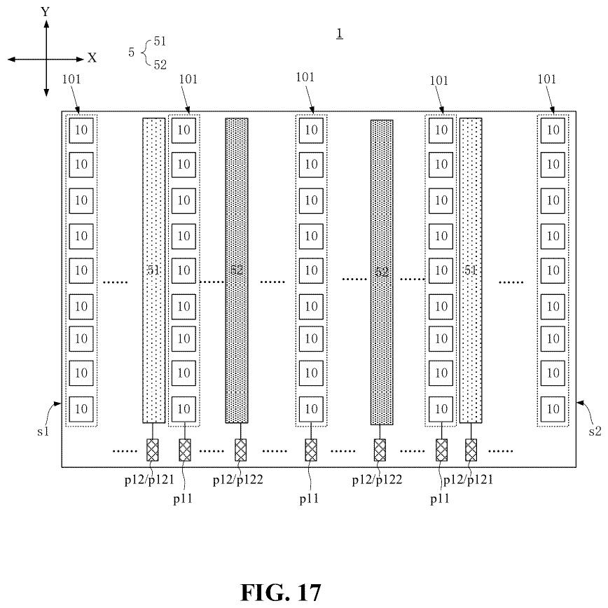

In some embodiments, as shown in FIG. 17, the display substrate 1 includes a plurality of pixel circuit columns 101 arranged in a first direction X, and the pixel circuit column 101 includes a plurality of pixel circuits 10 arranged in a second direction Y. The numbers of pixel circuit columns 101 spaced between different scan driving circuits 5 are different, and the numbers of first data bonding pads p11 spaced between different first scan bonding pads p12 are different.

Exemplarily, multiple pixel circuit columns 101 and multiple first data bonding pads p11 can be electrically connected in one-to-one correspondence.

As an example, the more pixel circuit columns 101 are spaced between two scan driving circuits 5, the more first data bonding pads p11 are spaced between the first scan bonding pads p12 electrically connected to the two scan driving circuits 5.

In this embodiment, the numbers of pixel circuit columns 101 between different scan driving circuits 5 are different, and the numbers of first data bonding pads p11 between different first scan bonding pads p12 are also different. The arrangement rule of multiple first scan bonding pads p12 and multiple first data bonding pads p11 in the first area can follow the arrangement rule of multiple scan driving circuits 5 and multiple pixel circuit columns 101 that are electrically connected to the first bonding pads of the first area. In this way, it is convenient to connect multiple first scan bonding pads p12 and multiple first scan bonding pads p12 nearby, and it is convenient to connect multiple first data bonding pads p11 and multiple pixel circuit columns 101 nearby.

In some embodiments, as shown in FIG. 17, the scan driving circuit 5 includes a first scan driving circuit 51 and a second scan driving circuit 52, the first scan bonding pad p12 includes a first scan driving bonding sub-pad p121 and a second scan driving bonding sub-pad p122, the first scan driving circuit 51 is electrically connected to the first scan driving bonding sub-pad p121, and the second scan driving circuit 52 is electrically connected to the second scan driving bonding sub-pad p122.

The number of pixel circuit columns 101 spaced between the first scan driving circuit 51 and the second scan driving circuit 52 is the same as the number of first data bonding pads p11 spaced between the first scan driving bonding sub-pad p121 and the second scan driving bonding sub-pad p122.

The first scan driving circuit 51 and the second scan driving circuit 52 are configured to provide different scan signals to the pixel circuit 10. For example, the pixel circuit includes a data writing transistor and a light emitting control transistor, the output end of the first scan driving circuit 51 is electrically connected to the gate of the data writing transistor, and the output end of the second scan driving circuit 52 is electrically connected to the gate of the light emitting control transistor.

For another example, at least one of the first scan driving circuit 51 and the second scan driving circuit 52 is configured to provide a sweep frequency signal SWEEP to the pixel circuit 10.

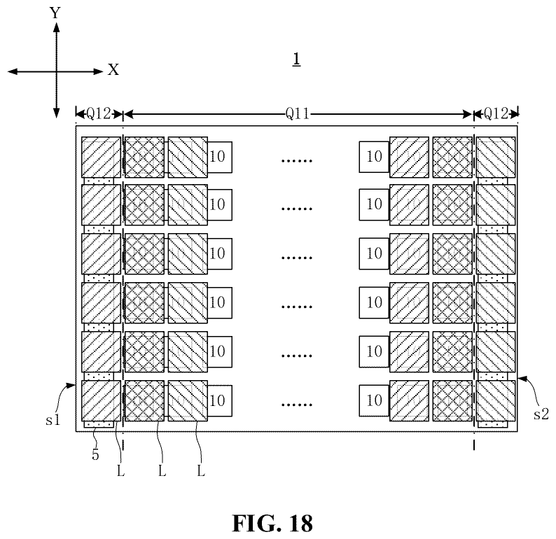

In some other embodiments, as shown in FIG. 18, in the first direction X, the display substrate 1 includes a central area Q11 and an edge area Q12, the pixel circuit 10 is located in the central area Q11, the scan driving circuit 5 is located in the edge area Q12, and light-emitting elements L are provided in both the central area Q11 and the edge area Q12 and overlap at least partially with the pixel circuits 10, and the pixel circuits 10 overlap at least partially with the scan driving circuits 5. It should be noted that FIG. 18 takes for example that the scan driving circuits 5 are provided on both sides of the central area Q11. In other examples, the scan driving circuit 5 may also be provided only on one side of the central area Q11.

The above exemplary introductions are some examples of the first scan bonding pad and the first data bonding pad.

The following introduces some examples of the first bonding pad of the second area.

In some embodiments, as shown in FIG. 15 or FIG. 16, in the first direction X, a plurality of first power supply bonding pads p13 in the second area BA2 are interspersed between a plurality of first data bonding pads p11.

As an example, as shown in FIG. 8 or FIG. 11, the first bonding pad for transmitting power supply signals PVDD and PVEE is a first power supply bonding pad p13, and the second area BA2 includes a plurality of first power supply bonding pads p13 and a plurality of first data bonding pads p11. In the first direction X, a plurality of first power supply bonding pads p13 in the second area BA2 are interspersed between a plurality of first data bonding pads p11, including but not limited to the following examples.

For example, in the first direction X, the first bonding pads in at least part of the second area BA2 are arranged in the order of first data bonding pad, first power supply bonding pad, first data bonding pad, and first power supply bonding pad, that is, in the first direction X, there is a first power supply bonding pad between every two adjacent first data bonding pads in at least part of the second area BA2, and there is a first data bonding pad between every two adjacent first voltage bonding pads.

For another example, in the first direction X, there is at least one first power supply bonding pad between at least two adjacent first data bonding pads in the second area BA2, and/or there are multiple first data bonding pads between at least two adjacent first power supply bonding pads.

It can be understood that there is a first power supply bonding pad between at least two adjacent first data bonding pads in the second area BA2, which can be regarded as multiple first power supply bonding pads p13 in the second area BA2 interspersed between multiple first data bonding pads p11.

In a large-size display panel, the number of pixel circuit columns is large, and multiple pixel circuit columns are usually evenly arranged in the first direction. In this embodiment, multiple first power supply bonding pads p13 in the second area BA2 are interspersed between multiple first data bonding pads p11, and multiple first power supply bonding pads p13 can provide power supply signals to multiple pixel circuit columns at multiple positions, which is conducive to uniformly providing power supply signals to the pixel circuits of the entire display area to improve display uniformity.

Exemplarily, as shown in FIG. 8 or FIG. 11, in the first direction X, multiple first power supply bonding pads p13 can be located in the central area of the second area BA2.

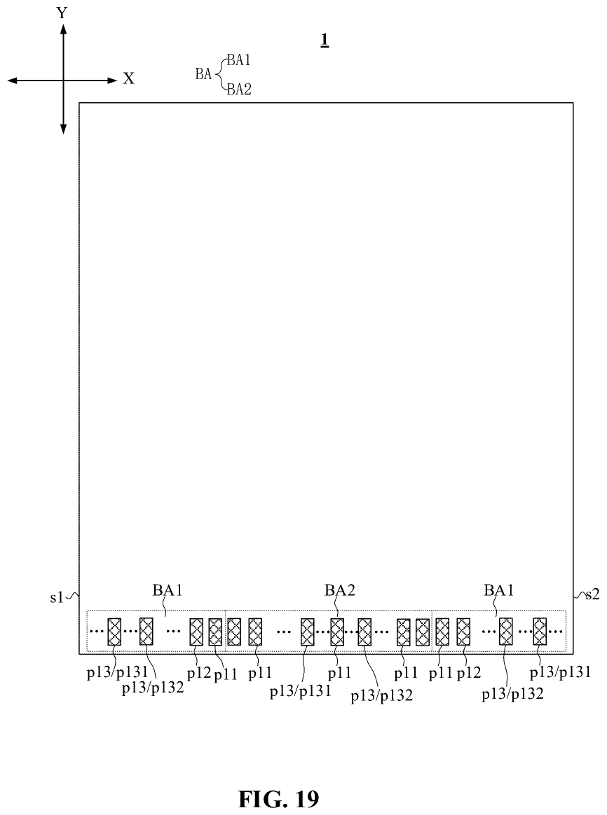

In other embodiments, as shown in FIG. 19, the first area BA1 may further include first power supply bonding pads p13. In this way, the first power supply bonding pad p13 in the first area BA1 may also provide a power supply signal to the pixel circuit to further improve display uniformity.

In some embodiments, as shown in FIG. 19, the first power supply bonding pad p13 includes a first power supply bonding sub-pad p131 and a second power supply bonding sub-pad p132, and the voltage transmitted by the first power supply bonding sub-pad p131 is greater than the voltage transmitted by the second power supply bonding sub-pad p132. For example, the first power supply bonding sub-pad p131 transmits a power supply signal PVDD, and the second power supply bonding sub-pad p132 transmits a power supply signal PVEE.

The number of first power supply bonding sub-pads p131 in the first area BA1 is less than the number of first power supply bonding sub-pads p131 in the second area BA2, and/or the number of second power supply bonding sub-pads p132 in the first area BA1 is less than the number of second power supply bonding sub-pads p132 in the second area BA2.

Since the first scan bonding pad p12 is further required in the first area BA1, the number of the first power supply bonding sub-pads p131 in the first area BA1 is set to be small, and/or the number of the second power supply bonding sub-pads p132 in the first area BA1 is set to be small, so as to ensure that there is enough space to accommodate the first scan bonding pads p12.

Some examples of the first bonding pad in the second area are introduced above.

Some examples of the driver chip are introduced below.

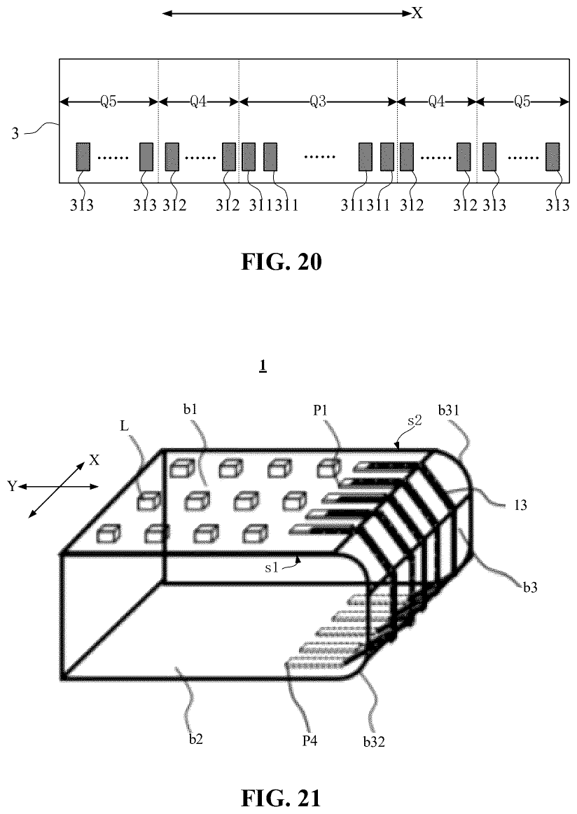

In some embodiments, as shown in FIG. 20, the pins of the driver chip 3 include a data pin 311, a scan pin 312 and a power supply pin 313, the data pin 311 transmits a data signal, the scan pin 312 transmits a scan driving signal, and the power supply pin 313 transmits a power supply signal. The data signal, the scan driving signal and the power supply signal belong to different types of signals.

The driver chip 3 includes a third area Q3, a fourth area Q4 and a fifth area Q5, the third area Q3 includes a data pin 311, the fourth area Q4 includes a scan pin 312, and the fifth area Q5 includes a power supply pin 313.

Exemplarily, the third area Q3 includes a plurality of data pins 311, and the plurality of data pins 311 are respectively configured to transmit data signals required by light-emitting elements of different luminous colors located in different columns. The fourth area Q4 includes a plurality of scan pins 312, and the plurality of scan pins 312 are respectively configured to transmit different scan driving signals. The fifth area Q5 includes a plurality of power supply pins 313, and the power supply pins 313 include pins for transmitting power supply signals PVDD and PVEE respectively. The power supply pin 313 for transmitting the power supply signal PVDD may include a plurality of pins, and/or the power supply pin 313 for transmitting the power supply signal PVEE may include a plurality of pins.

In this embodiment, the pins for transmitting different types of signals are respectively arranged in different areas of the driver chip, which can reduce interference between different types of signals.

For example, referring to FIG. 20 in combination with FIG. 8 or FIG. 11, a pin 3 for transmitting data signals R1-Rn, G1-Gn, and B1-Bn is the data pin, a pin 3 for transmitting scan driving signals STV1-STV3, Scan1-Scan3, and Emit1-Emit3 is the scan pin, and a pin 3 for transmitting power supply signals PVDD and PVEE is the power supply pin.

The first bonding pad P1, the second bonding pad P2, the third bonding pad P3, and the pin 3 for transmitting the same signal are electrically connected to each other. Specifically, the first bonding pad P1, the second bonding pad P2, the third bonding pad P3, and the pin 3 for transmitting the data signal R1 are electrically connected to each other, the first bonding pad P1, the second bonding pad P2, the third bonding pad P3, and the pin 3 for transmitting the data signal R2 are electrically connected to each other, and so on, the first bonding pad P1, the second bonding pad P2, the third bonding pad P3, and the pin 3 for transmitting the data signal Rn are electrically connected to each other. Similarly, the first bonding pad P1, the second bonding pad P2, the third bonding pad P3, and the pin 3 for transmitting the data signal G1 are electrically connected to each other, the first bonding pad P1, the second bonding pad P2, the third bonding pad P3, and the pin 3 for transmitting the data signal B1 are electrically connected to each other, the first bonding pad P1, the second bonding pad P2, the third bonding pad P3, and the pin 3 for transmitting the scan driving signal STV1 are electrically connected to each other, the first bonding pad P1, the second bonding pad P2, the third bonding pad P3, and the pin 3 for transmitting the power supply signal PVDD are electrically connected to each other; and so on.

In some embodiments, in the first direction X, the fourth area Q4 is located between the third area Q3 and the fifth area Q5.

In some embodiments, in the first direction X, the fourth areas Q4 are disposed on both sides of the third area Q3, and the fifth areas Q5 are disposed on both sides of the third area Q3.

Some examples of driver chips are introduced above.

Some examples of display substrates are introduced below.

In some embodiments, as shown in FIG. 21, the display substrate 1 further includes a fourth bonding pad P4 and a second connecting line 13, the first bonding pad P1 and the fourth bonding pad P4 are located on opposite sides of the display substrate 1, and the second connecting line 13 electrically connects the first bonding pad P1 and the fourth bonding pad P4.

The display substrate 1 includes a light-emitting surface b1 and a backlight surface b2, and the light-emitting surface b1 and the backlight surface b2 are opposite. The light-emitting surface b1 of the display substrate 1 is its light-emitting side, and the backlight surface b2 of the display substrate 1 is its backlight side. One of the first bonding pad P1 and the fourth bonding pad P4 is located on the light-emitting side, and the other is located on the backlight side. The light-emitting surface b1 and the backlight surface b2 are two surfaces opposite to each other in the thickness direction of the display substrate 1, and the light-emitting surface b1 and the backlight surface b2 are connected by the side surface.

As an example, as shown in FIG. 21, the first bonding pad P1 is located on the light-emitting side of the display substrate 1, and the fourth bonding pad P4 is located on the backlight side of the display substrate 1.

Referring to FIG. 1 and FIG. 21, the first circuit board 2 and the driver chip 3 are located on the backlight side of the display substrate 1, and the second bonding pad P2 and the fourth bonding pad P4 of the first circuit board 2 can be press-fitted and connected. The signal provided by the driver chip 3 is transmitted to the first bonding pad P1 through pin 3, the third bonding pad P3, the second bonding pad P2, and the fourth bonding pad P4 in sequence.

In large-size display products, multiple display modules need to be spliced together. The splicing gap can be reduced, and even seamless splicing can be achieved by adopting the design of the second connecting line.

Exemplarily, the connection position between the light-emitting surface b1 and the side surface b3 can be chamfered to form a first transition surface b31, and the connection position between the backlight surface b2 and the side surface b3 can be chamfered to form a second transition surface b32. The transition surface is formed by chamfering so that the second connecting line 13 may not be bent at a right angle, and the second connecting line 13 is not easy to fall off, thereby improving reliability.

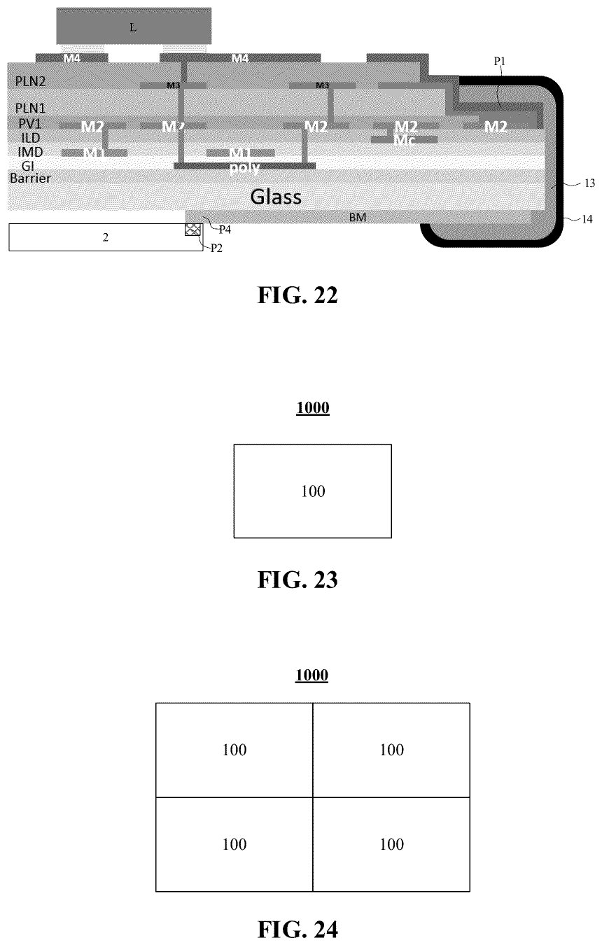

In some embodiments, as shown in FIG. 22, the backlight side of the display substrate includes a metal layer BM, and the fourth bonding pad P4 is located on the metal layer BM on the backlight side of the display substrate 1.

Exemplarily, the display substrate includes a substrate Glass (the substrate includes but is not limited to a glass substrate), a buffer layer Barrier, a semiconductor layer (the material of the semiconductor layer includes but is not limited to polysilicon poly), a first metal layer M1, a capacitor metal layer Mc, a second metal layer M2, a third metal layer M3, a fourth metal layer M4, a metal layer BM, and a gate insulating layer G1, a capacitor insulating layer IMD, an interlayer dielectric layer ILD, an insulating layer PV1, a first planarization layer PLN1, and a second planarization layer PLN2. The stacking relationship of the film layers is shown in FIG. 19 and may not be described here.

The metal layer BM is located on the side of the substrate Glass facing away from the semiconductor layer poly. Since different metal layers need to be insulated by an insulating layer, when there is only one metal layer BM on the backlight side of the display substrate, there is no need to prepare an insulating layer on the side of the substrate Glass facing away from the semiconductor layer poly. Compared with the display panel having multiple metal layers on the backlight side, this embodiment can reduce the number of the film layers of the display substrate, thereby simplifying the preparation process of the display substrate. In addition, it is precisely because there is only one metal layer on the backlight side of the display substrate that it is impossible to directly achieve signal rearrangement through the metal layer on the backlight side, and thus a first circuit board is provided for signal rearrangement.

Exemplarily, as shown in FIG. 22, the second bonding pad P2 of the first circuit board 2 is connected to the fourth bonding pad P4.

In some embodiments, as shown in FIG. 21, a plurality of fourth bonding pads P4 are arranged in the first direction X, and the i^{th} first bonding pad P1 is electrically connected to the i^{th} fourth bonding pad P4 in the direction from the first edge s1 to the second edge s2.

For example, in the direction from the first edge s1 to the second edge s2, the 1st first bonding pad P1, the 2nd first bonding pad P1, the 3rd first bonding pad P1 . . . are arranged in sequence. In the direction from the first edge s1 to the second edge s2, the 1st fourth bonding pad P4, the 2nd fourth bonding pad P4, the 3rd fourth bonding pad P4 . . . are arranged in sequence. The i^{th} first bonding pad P1 is any first bonding pad in the display substrate, the i^{th} fourth bonding pad P4 is any fourth bonding pad in the display substrate, and the i^{th} first bonding pad P1 and the i^{th} fourth bonding pad P4 are arranged in the same order.

Exemplarily, the number of first bonding pads P1 and the number of fourth bonding pads P4 are the same. Multiple first bonding pads P1 and multiple fourth bonding pads P4 are electrically connected in one-to-one correspondence through multiple second connecting lines 13. In this way, the situation where the second connecting lines 13 cross can be avoided, and the difficulty of preparing the second connecting lines 13 is reduced.

In some embodiments, multiple first bonding pads P1 and fourth bonding pads P4 with the same arrangement order are electrically connected to each other.

Specifically, in the direction from the first edge s1 to the second edge s2, the 1st first bonding pad P1 and the 1st fourth bonding pad P4 are electrically connected through the first second connecting line 13, and the signals transmitted by the 1st first bonding pad P1 and the 1st fourth bonding pad P4 are the same; the 2nd first bonding pad P1 and the 2nd fourth bonding pad P4 are electrically connected through the 2nd second connecting line 13, and the signals transmitted by the 2nd first bonding pad P1 and the 2nd fourth bonding pad P4 are the same; the 3rd first bonding pad P1 and the 3rd fourth bonding pad P4 are electrically connected through the third second connecting line 13, and the signals transmitted by the 3rd first bonding pad P1 and the 3rd fourth bonding pad P4 are the same; and so on, the last first bonding pad P1 and the last fourth bonding pad P4 are electrically connected through the last second connecting line 13, and the signals transmitted by the last first bonding pad P1 and the last fourth bonding pad P4 are the same.

In this embodiment, a plurality of first bonding pads P1 and fourth bonding pads P4 with the same arrangement order are electrically connected to each other, and the signals transmitted by the plurality of first bonding pads P1 and fourth bonding pads P4 with the same arrangement order are the same, and there is no need to rearrange the signals, so that the plurality of second connecting lines 13 can occupy one metal layer.

Based on the same technical concept, the embodiments of the present application also provide a display apparatus. As shown in FIG. 23, the display apparatus 1000 includes a display module 100 as described in any one of the above embodiments. The display apparatus 1000 includes at least one display module 100.

The display apparatus provided in the embodiments of the present application may be a mobile phone, a computer, a television, a car display apparatus or other display apparatus with display function, and the present application does not make specific restrictions on this. The display apparatus provided in the embodiments of the present application has the beneficial effects of the display module provided in the embodiments of the present application, and the specific description of the display module in the above embodiments can be referred to, and the present embodiment may not be repeated here.

In some embodiments, as shown in FIG. 24, the display apparatus 1000 includes a plurality of display modules 100, and at least two display modules 100 are spliced. In this embodiment, large-size display, seamless splicing, and narrow-bezel display of the display apparatus can be realized.

According to the embodiments described above in the present application, these embodiments do not describe all the details in detail, nor do they limit the present application to the specific embodiments described. Apparently, according to the above description, many modifications and changes can be made. This specification selects and describes these embodiments in detail in order to better explain the principles and practical applications of the present application, so that those skilled in the art can make good use of the present application and the modified use based on the present application. The present application is only limited by the claims and their full scope and equivalents.

What is claimed is:

1. A display module, comprising:
a display substrate, comprising a plurality of first bonding pads arranged in a first direction, the display substrate comprising a first edge and a second edge opposite to each other in the first direction;
a first circuit board, comprising a plurality of first connecting lines, a plurality of second bonding pads arranged in the first direction, and a plurality of third bonding pads arranged in the first direction, at least one of the second bonding pads being electrically connected to a corresponding one of the first bonding pads, an end of at least one of the first connecting lines being connected to a corresponding one of the second bonding pads, and the other end of the at least one of the first connecting lines being connected to a corresponding one of the third bonding pads; and
a driving chip, comprising a plurality of pins arranged in the first direction, the pins being electrically connected to the third bonding pads,
wherein in a direction from the first edge to the second edge, signals transmitted by the i^{th} one of the second bonding pads and the i^{th} one of the third bonding pads are different, where i≥1, and i is an integer.

2. The display module according to claim 1, wherein in the direction from the first edge to the second edge, signals transmitted by the i^{th} one of the first bonding pads and the i^{th} second bonding pad are same, and signals transmitted by the i^{th} third bonding pad and an i^{th} one of the pins are same; or
wherein in the direction from the first edge to the second edge, the plurality of second bonding pads and the plurality of pins are arranged in a same arrangement order and transmit different signals; or
wherein in the direction from the first edge to the second edge, signals transmitted by the j^{th} one of the second bonding pads and the j^{th} one of the pins are same, where i≠j, j≥1, and j is an integer.

3. The display module according to claim 1, wherein the first circuit board comprises a plurality of metal layers arranged in insulation, and cross portions of different ones of the first connecting lines are arranged in the different metal layers; or
wherein the second bonding pads are located on a first side of the first circuit board, the third bonding pads are located on a second side of the first circuit board, and the first side and the second side are opposite in a thickness direction of the first circuit board.

4. The display module according to claim 1, wherein the first circuit board is electrically connected to a plurality of the driver chips, and in the direction from the first edge to the second edge, signals transmitted by the k^{th} ones of the pins in the different driver chips are same, where k≥1, and k is an integer.

5. The display module according to claim 4, wherein in the direction from the first edge to the second edge, in the plurality of the driver chips, arrangement orders of the plurality of pins are same and signals transmitted by the plurality of pins are same; or
the display module comprises a plurality of the first circuit boards, and the different first circuit boards are electrically connected to the different first bonding pads; and
in the direction from the first edge to the second edge, signals transmitted by the s^{th} ones of the second bonding pads in the different first circuit boards are different, where s≥1, and s is an integer.

6. The display module according to claim 1, wherein the plurality of first bonding pads comprise a first data bonding pad, a first scan bonding pad, and a first power supply bonding pad, the first data bonding pad transmitting a data signal, the first scan bonding pad transmitting a scan driving signal, and the first power supply bonding pad transmitting a power supply signal; and
the display substrate comprises a binding area, which comprises a first area and a second area, the first area comprising the first data bonding pad and the first scan bonding pad, and the second area comprising the first data bonding pad and the first power supply bonding pad.

7. The display module according to claim 6, wherein the display substrate comprises a scan driving circuit electrically connected to the first scan bonding pad,
in a second direction, the scan driving circuit at least partially overlaps with the first area, and the scan driving circuit does not overlap with the second area, and the first direction intersects the second direction.

8. The display module according to claim 7, wherein the display substrate comprises a first center line and a second center line that extend in the second direction, a distance between the first center line and the first edge in the first direction being D/2 where D is a width of the display substrate in the first direction, a distance between the second center line and the first center line in the first direction being D/4, and the scan driving circuit being adjacent to the second center line; and
in the second direction, the first area overlaps with the second center line, and the second area overlaps with the first center line.

9. The display module according to claim 8, wherein in the first direction, a plurality of the first data bonding pads and a plurality of the first scan bonding pads in the first area are arranged crosswise.

10. The display module according to claim 9, wherein in the first direction, the first scan bonding pad on a first side of the first data bonding pad in the first area transmits a first scan driving signal, and the first scan bonding pad on a second side of the first data bonding pad in the first area transmits a second scan driving signal.

11. The display module according to claim 8, wherein the display substrate comprises a plurality of pixel circuit columns arranged in the first direction, numbers of the pixel circuit columns between the different scan driving circuits are different, and numbers of the first data bonding pads between the different first scan bonding pads are different;
the scan driving circuits comprise a first scan driving circuit and a second scan driving circuit, the first scan bonding pad comprises a first scan driving bonding sub-pad and a second scan driving bonding sub-pad, the first scan driving circuit is electrically connected to the first scan driving bonding sub-pad, and the second scan driving circuit is electrically connected to the second scan driving bonding sub-pad; and
a number of the pixel circuit columns between the first scan driving circuit and the second scan driving circuit is the same as a number of the first data bonding pads between the first scan driving bonding sub-pad and the second scan driving bonding sub-pad.

12. The display module according to claim 6, wherein the first area further comprises the first power supply bonding pad;
the first power supply bonding pad comprises a first power supply bonding sub-pad and a second power supply bonding sub-pad, and a voltage transmitted by the first power supply bonding sub-pad is greater than a voltage transmitted by the second power supply bonding sub-pad; and
a number of the first power supply bonding sub-pads in the first area is less than a number of the first power supply bonding sub-pads in the second area, and/or a number of the second power supply bonding sub-pads in the first area is less than a number of the second power supply bonding sub-pads in the second area.

13. The display module according to claim 1, wherein the pins comprise data pins, scan pins, and power supply pins, the data pins transmitting data signals, the scan pins transmitting scan driving signals, and the power supply pins transmitting power supply signals; and
the driver chip comprises a third area, a fourth area, and a fifth area, the third area comprising the data pins, the fourth area comprising the scan pins, and the fifth area comprising the power supply pins.

14. The display module according to claim 13, wherein the fourth area is located between the third area and the fifth area in the first direction.

15. The display module according to claim 1, wherein the display substrate further comprises fourth bonding pads and second connecting lines, each of the first bonding pads and each of the fourth bonding pads are located on opposite sides of the display substrate respectively, and each of the second connecting lines is electrically connected to one of the first bonding pads and one of the fourth bonding pads.

16. The display module according to claim 15, wherein the first bonding pads are located on a light-emitting side of the display substrate, and the fourth bonding pads are located on a backlight side of the display substrate.

17. The display module according to claim 16, wherein the backlight side of the display substrate comprises a metal layer, and the fourth bonding pads are located on the metal layer.

18. The display module according to claim 15, wherein a plurality of the fourth bonding pads are arranged in the first direction, and in the direction from the first edge to the second edge, the i^{th} one of the first bonding pads is electrically connected to the i^{th} one of the fourth bonding pads.

19. The display module according to claim 18, wherein the plurality of first bonding pads and the plurality of fourth bonding pads that are arranged in a same order are electrically connected to each other.

20. A display apparatus, comprising a display module which comprises:
a display substrate, comprising a plurality of first bonding pads arranged in a first direction, the display substrate comprising a first edge and a second edge opposite to each other in the first direction;
a first circuit board, comprising a plurality of first connecting lines, a plurality of second bonding pads arranged in the first direction, and a plurality of third bonding pads arranged in the first direction, at least one of the second bonding pads being electrically connected to a corresponding one of the first bonding pads, an end of at least one of the first connecting lines being connected to a corresponding one of the second bonding pads, and the other end of the at least one of the first connecting lines being connected to a corresponding one of the third bonding pads; and
a driving chip, comprising a plurality of pins arranged in the first direction, the pins being electrically connected to the third bonding pads,
wherein in a direction from the first edge to the second edge, signals transmitted by the i^{th} one of the second bonding pads and the i^{th} one of the third bonding pads are different, where i≥1, and i is an integer.
